(19) United States
(12) Patent Application Publication
(10) Pub. No.: US 2025/0105083 A1
(43) Pub. Date: Mar. 27, 2025

(54) ELECTRONIC MODULE CONFIGURED FOR THERMAL MANAGEMENT

(71) Applicants: Analog Power Conversion LLC, Bend, OR (US); Kyosan Electric Manufacturing Co., Ltd., Yokohama (JP)

(72) Inventors: Amaury Gendron-Hansen, Bend, OR (US); Wang-Chang Albert Gu, Bend, OR (US); Dumitru Gheorge Sdrulla, Bend, OR (US); Tetsuya Takata, Yokohama (JP); Itsuo Yuzurihara, Yokohama (JP); Tomohiro Yoneyama, Yokohama (JP); Yu Hosoyamada, Yokohama (JP)

(21) Appl. No.: 18/476,058

(22) Filed: Sep. 27, 2023

(51) Int. Cl. H01L 23/367; H01L 25/07

(52) U.S. Cl. CPC H01L 23/367; H01L 25/072

(57) ABSTRACT

An electronic module performing a power function comprises a substrate and a plurality of semiconductor dies disposed on the substrate. The plurality of semiconductor dies operates together to perform a power device function. The semiconductor dies may be identical. The semiconductor die may have a high length-to-width (i.e. aspect) ratio in order to improve the thermal performance of the electronic module. The semiconductor die may be disposed on the substrate in a uniformly spaced pattern to improve the thermal performance, which pattern may be a hexagonal pattern, a linear pattern, or a rectangular pattern. The electronic module may also comprise a driver device coupled to and configured to control the plurality of semiconductor dies. The driver device may be disposed on the substrate between a first semiconductor die of the plurality of semiconductor dies and a second semiconductor die of the plurality of semiconductor dies.

### BACKGROUND

A semiconductor power device may be composed of a plurality of cells. For example, a silicon carbide (SiC) Vertical Metal-Oxide-Semiconductor Field Effect Transistor (VMOSFET) may include a plurality of cells, each including its own gate electrode and associated gate pad, source region(s) and associated source pad(s), and drain contact, which in a vertical device such as a VMOSFET may be disposed over a surface of the die opposite the surface over which the gate and source pads are disposed. The cells may be disposed in a semiconductor die in compact active areas (called tubs), each tub being separated from other tubs by inactive areas of the semiconductor die.

A Safe Operating Area (SOA) of such a power device may be limited on the high-current high-voltage side by thermal instability triggered by the negative temperature coefficient of the threshold voltage Vₜₕ of the cells. Both the bias conditions and the die temperature of the cells play a role in the thermal instability of the cell.

Furthermore, non-uniformity of the turn-on voltage from cell to cell may cause one or several cells to “steal” most if not all the drain current. Due to the negative temperature coefficient of the threshold voltage Vₜₕ, the cells with increased current will have an even lower threshold voltage Vₜₕ and will start conducting even more current. This produces a local self-heating phenomenon that may result in permanent damage of those cells.

Because of these and other factors, high junction temperature during operation is the leading cause for failures and compromised long-term reliability of semiconductor power devices.

Historically, engineering and economic advantages of integration have tended to favor power electronic modules using a smaller number of large-die-size semiconductor devices.

However, a semiconductor power device with high packing density tends to have a hot spot at its geometric center, and the degree to which the hot spot temperature exceeds the average temperature of the semiconductor power device tends to increase as the die size increases.

Furthermore, a semiconductor power device with multiple tubs, where the packing density is not as high, can experience cross-heating between the tubs, which may become especially problematic when one or more of the tubs suffer from degraded operational characteristics. Furthermore, the inactive areas between the tubs may increase a total amount of semiconductor “real estate” used by semiconductor power device, thus decreasing per-wafer yields and increasing costs of the semiconductor power device.

Additionally, limitations of techniques used to improve thermal performance in the related arts may impose restrictions on a physical configuration of the semiconductor power device which may degrade the electrical performance of the semiconductor power device, such as by increasing parasitic inductances and the like.

Accordingly, a need exists to improve the long-term reliability and life, decrease the cost, and improve the thermal and electrical performance of semiconductor power devices.

### SUMMARY OF THE INVENTION

Embodiments relate to electronic modules, for example modules for radio frequency (RF) power conversion. Embodiments include at least one semiconductor device placed on a substrate. The semiconductor device may be a silicon carbide (SiC) power device for high-power applications, such as a VMOSFET. The substrate may be an insulator material with respect to electric current such as beryllium oxide (BO), aluminum nitride (AlN), or silicon nitride (Si3N4). Embodiments operate to decrease the maximum operating temperature within an electronic module by partitioning the functionality of the semiconductor device into a plurality of semiconductor dies, wherein the semiconductor dies have a high aspect ratio, are disposed on a substrate in a manner that optimizes thermal properties of the electronic module, or combinations thereof.

In an embodiment, an electronic module comprises a substrate and a plurality of semiconductor dies disposed on the substrate. The plurality of semiconductor dies operate together to perform a power device function, and the plurality of semiconductor dies are shaped, disposed on the substrate, or both to improve a thermal performance of the electronic module.

In an embodiment, the electronic module further comprises a driver device coupled to and configured to control the plurality of semiconductor dies. The driver device may be disposed on the substrate between a first semiconductor die of the plurality of semiconductor dies and a second semiconductor die of the plurality of semiconductor dies, or between a first group of two or more of the semiconductor dies and a second group comprising a different two or more of the semiconductor dies.

A length of a semiconductor die may be four or more times a width of the semiconductor die in some embodiments, or may be eight or more times the width in other embodiments.

### BRIEF DESCRIPTION OF THE DRAWINGS

FIGS. 1A and 1B illustrates an electronic module and a thermal analysis thereof.

FIG. 2 is a plan view of an electronic module according to an embodiment.

FIG. 3 is a plan view of an electronic module according to another embodiment.

FIG. 4 is a plan view of an electronic module according to another embodiment.

FIG. 5 is a plan view of an electronic module according to another embodiment.

FIG. 6 is a plan view of an electronic module according to another embodiment.

FIG. 7 is a plan view of an electronic module according to another embodiment.

FIG. 8A is a plan view of an electronic module according to another embodiment.

FIG. 8B is a thermal analysis of the electronic module of FIG. 8A according to an embodiment.

FIG. 9 is a thermal analysis of an electronic module.

FIG. 10 is a thermal analysis of an electronic module according to an embodiment.

### DETAILED DESCRIPTION

Embodiments of the present application relate to a configuration of an electronic module to improve thermal performance, reduce an amount of semiconductor real estate needed to implement the device, or both. Embodiments may configure the semiconductor device within the electronic module into a plurality of semiconductor dies having a high aspect ratio, being smaller, being disposed in an optimized manner on a substrate, or combinations thereof. The plurality of semiconductor dies may each have one tub or may each include a plurality of tubs. Embodiments promote greater temperature uniformity among the tubs of the semiconductor dies, which may improve the long-term reliability and life of the electronic module. In embodiments, the semiconductor device may be a power device such as a silicon carbide (SiC) Vertical Metal-Oxide-Semiconductor Field Effect Transistor (VMOSFET) or a SiC Vertical Insulated Gate Bipolar Transistor (VIGBT), but embodiments are not limited thereto.

Although embodiments presented herein may be described with respect to SiC technology, embodiments are not limited thereto, an in other embodiments, other semiconductor technology, including wide bandgap (WBG) or ultra-wide bandgap (UWGB) technology, may be used instead, such as technologies based on silicon, gallium nitride (GaN), aluminum gallium nitride (AlGaN), high aluminum content AlGaN, beta gallium trioxide (β-Ga₂O₃), diamond, boron nitrides, and the like. For example, embodiments may use GaN instead of SiC. Other embodiments may use a polytype of SiC other than 4H, such as 3C-SiC.

A detailed description of embodiments is provided below along with accompanying figures. The scope of this disclosure is limited only by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. Furthermore, features in drawings may not all be drawn to the same scale, may be exaggerated in one or more dimensions, or both in the interest of clarity.

A power device should be able to dissipate a large amount of power and should therefore have a low thermal resistance so that heat can easily flow out of the device. For high and very high frequency power conversion, the device should also provide a high conversion efficiency, and accordingly should have low input, output, and reverse capacitances. Historically, these requirements respectively translate to a large die size and a low active area, where the active area is the sum of the areas of the active regions of the device. In commercial MOSFETs of the related arts, the die size and active area are closely linked and cannot be tuned independently from each other.

Embodiments may be incorporated in an electronic module formed of a plurality of cells of the power device in a plurality of separated active regions (tubs) on a plurality of semiconductor dies. In some embodiments, each of the semiconductor die includes a plurality of cells in respective tubs, wherein the tubs are spaced apart; that is, separated by inactive portions of the semiconductor die, where an inactive region may be defined as a region that does not dissipate substantial power, does not perform the function required (designed) for a specific application of the semiconductor device, is not doped above a given threshold (e.g., dopant concentrations of 1.0E17 cm⁻³ or higher for SiC technology), or the like. In other embodiments, each of the semiconductor die includes only one tub, and may or may not include a substantial inactive region.

Respective control pads (for example, gate pads) may be provided for each active region. One or more pads for a conduction terminal of a first type (for example, one or more source pads) may be provided for each active region. Conduction terminals of a second type (for example, a drain) may be electrically coupled together to a single pad. When the device is a vertical device, the pads for the control terminals and the conduction terminals of the first type may be formed over one face (e.g., the top) of the dies, and the pad for the conduction terminals of the second type may be formed over an opposite face (e.g. the bottom) of the dies.

In embodiments, the dies of the plurality of dies are designed with a shape specifically chosen to enhance the thermal performance of the electronic module. For example, the dies may have a high aspect ratio; that is, a length of a die may be several times a width of the die.

In embodiments, the dies of the plurality of dies are disposed on a substrate in a pattern chosen to enhance the thermal performance of the electronic module. For example, the dies may be disposed in a hexagonal pattern, as discussed below.

In this way, the electronic module may produce a more uniform temperature over a surface of the die and improve the ability of the die to dissipate heat. Furthermore, the electronic module may decrease the cross-heating between dies that arises out of unavoidable heat spreading in the electronic module.

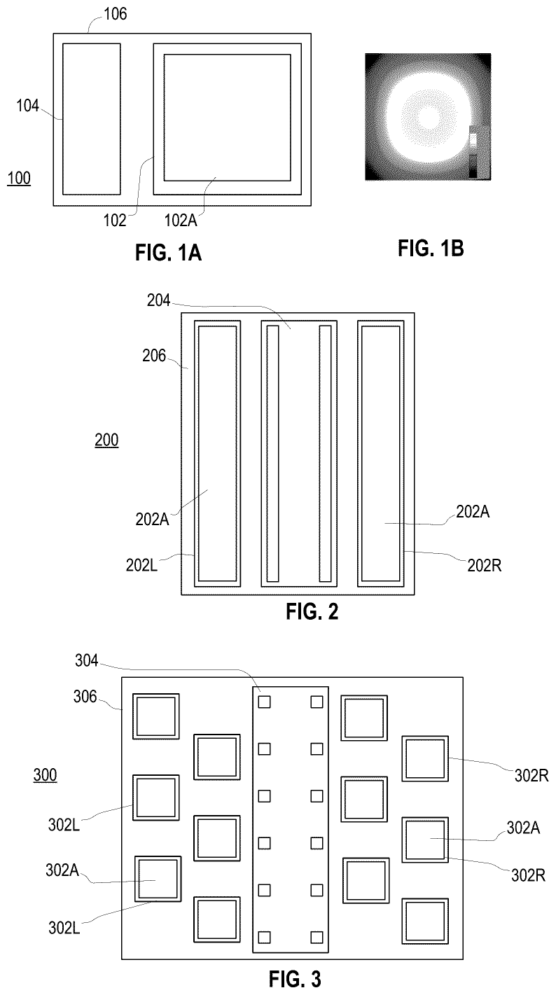

FIG. 1A illustrates a layout of an electronic module 100, and FIG. 1B illustrates a thermal analysis related thereto that may inform the design of an embodiment.

FIG. 1A shows an electronic module 100 including a driver device 104 and a semiconductor die 102 disposed on a substrate 106.

The semiconductor die 102 includes a tub 102A. The tub 102A may include cells of one or more semiconductor devices. In an embodiment, a single semiconductor device may have cells disposed in the tub 102A, but embodiments are not limited thereto; in other embodiments, a plurality of semiconductor devices may each have cells disposed in the tub 102A.

The driver device 104 is coupled to the semiconductor die 102 through interconnects (not shown) and controls operation of the semiconductor die 102. As techniques by which the driver device 104 may be coupled to and control the semiconductor die 102 are well-known in the related arts, they are omitted in the interest of brevity.

FIG. 1B shows results of a thermal analysis of the semiconductor die 102 under operating conditions. The results show projected operating temperatures on the top surface of the semiconductor die 102. In FIG. 1B, lighter areas correspond to relatively high (hotter) temperatures and darker areas correspond to relatively low (cooler) temperatures.

The thermal analysis may be a result produced by computer modelling, may be the result of thermal imaging of an operating semiconductor die, or may be a result of other methods of determining temperatures of a semiconductor die under operating conditions. Operating conditions may include both the electrical parameters (such as voltage, current, operating frequency, and load characteristic) of the semiconductor die and the thermal environment (such as ambient temperature, mechanical configuration, and cooling mechanisms) in which the electronic module operates.

As shown in FIG. 1B, projected operating temperatures at any point on the semiconductor die 102 under operating conditions may vary according to a location of within the tub 102A. For example, FIG. 1 shows top surface temperatures in the periphery of the tub 102A are substantially lower than top surface temperatures in a central portion of tub 102A. In an illustrative example, a difference between lowest and highest operating temperatures in the tubs 102A may be up to 33° C.

As used in this document, an operating temperature refers to a temperature arising when the electronic module is performing the operation it is designed to perform in the operating environment it is designed to operate in. The operating temperature may or may not be the same as a maximum temperature that the electronic module is rated to operate at. For example, an electronic module containing a SiC power MOSFET may be rated to operate at junction temperatures of up to 200° C., but in order to ensure a safety margin, optimize system performance, or both may have a design maximum operating temperature of 150° C. in a target application and environment.

In embodiments, design parameters of the semiconductor die 102 may be determined in accordance with the projected operating temperatures and/or thermal characteristics thereof to produce a new design that provides the functions of the semiconductor die 102 with enhanced thermal performance. The design parameters that be determined may include the number of semiconductor dies used to implement the functions of the semiconductor die 102, overall dimensions (such as length, width, a ratio of length to width, or combinations thereof) of the semiconductor dies used to implement the functions, the disposition of the semiconductor dies on a substrate, or combinations thereof. The design parameters may successively be iterated based on the new design.

FIG. 2 is a plan view of an electronic module 200 according to an embodiment. The electronic module 200 includes a driver device 204 and a plurality of semiconductor dies comprising a left semiconductor die 202L and a right semiconductor die 202R, all disposed on a substrate 206. Each of the electronic module dies 202L and 202R includes a single tub 202A.

The driver device 204 may be coupled to and control the semiconductor dies 202L and 202R using techniques that are well-known in the related arts, which are omitted in the interest of brevity.

The semiconductor dies 202L and 202R operate together to provide the functions of the semiconductor die 102 of FIG. 1. Respective aspect ratios of the semiconductor dies 202L and 202R are selected to provide enhanced thermal performance compared to the semiconductor die 102: because operating temperatures in a tub (such as the tub 102A or the tub 202A) increase with increasing distance from the edge of the die, splitting the semiconductor die 102 into two semiconductor dies 202L and 202R and configuring each of the two semiconductor dies to be substantially longer than they are wide will operate to produce lower peak temperatures in the semiconductor dies 202L and 202R than would occur in the semiconductor die 102 under the same operating conditions. In embodiments, the aspect ratio of the semiconductor dies 202L and 202R is four or more, that is, the length of each semiconductor die is at least four times its width. In embodiments, the aspect ratio is eight or more.

Furthermore, splitting the semiconductor die 102 into two semiconductor dies 202L and 202R and disposing them on either side of the driver device 204 may operate to reduce the lengths of the interconnects between the driver device 204 and the semiconductor dies 202L and 202R, improving the electrical characteristics of those interconnects.

Finally, disposing the two semiconductor dies 202L and 202R created by splitting the semiconductor die 102 at spaced apart locations on the substrate 206 may further improve the thermal characteristics of the electronic module 200 by spreading out the thermal load on the substrate 206.

FIG. 3 is a plan view of an electronic module 300 according to another embodiment.

The electronic module 300 includes a driver device 304, a plurality of left semiconductor dies 302L, and a plurality of right semiconductor dies 302R, all disposed on a substrate 306. Each of the semiconductor dies 302L and 302R includes a single tub 302A.

The driver device 304 may be coupled to and control the semiconductor dies 302L and 302R using techniques that are well-known in the related arts, which are omitted in the interest of brevity.

The semiconductor dies 302L and 302R operate together to provide the functions of the semiconductor die 102 of FIG. 1. The number of and respective dimensions of the semiconductor dies 302L and 302R are selected to provide enhanced thermal performance compared to the semiconductor die 102: because operating temperatures in a tub (such as the tub 102A or the tub 302A) increase with increasing distance from the edge of the die, splitting the semiconductor die 102 into substantially smaller semiconductor dies 302L and 302R will operate to produce lower peak temperatures in the semiconductor dies 302L and 302R than would occur in the semiconductor die 102 under the same operating conditions.

Furthermore, splitting the semiconductor die 102 into smaller semiconductor dies 302L and 302R and disposing the smaller semiconductor dies 302L and 302R spaced apart from each other (and, in some embodiments, on either sides of the driver device 304) on the substrate 306 may further improve the thermal characteristics of the electronic module 300 by spreading out the thermal load on the substrate 306.

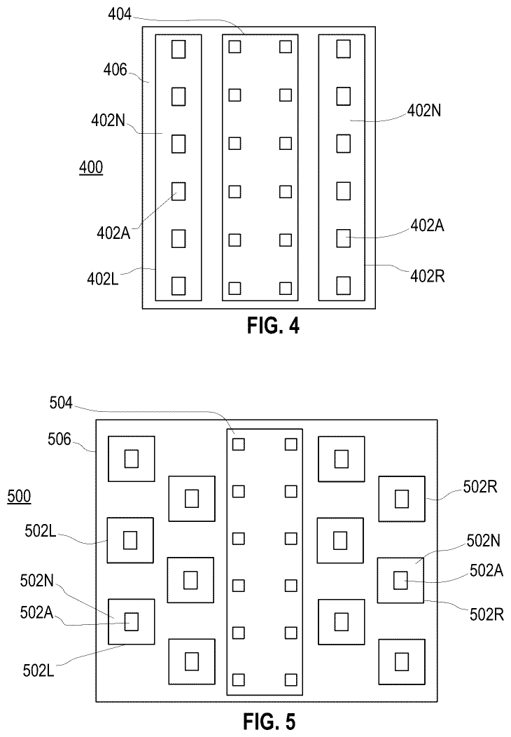

FIG. 4 is a plan view of an electronic module 400 according to another embodiment.

The electronic module 400 includes a driver device 404 and a plurality of semiconductor die comprising a left semiconductor die 402L and a right semiconductor die 402R, all disposed on a substrate 406. The semiconductor dies 402L and 402R differ from the semiconductor dies 202L and 202R of FIG. 2 in that each of the semiconductor dies 402L and 402R includes a plurality of tubs 402A spaced apart and surrounded by an inactive region 402N of each of the dies. In each semiconductor die, an area of the inactive region 402N may be substantially larger than combined areas of the plurality of tubs 402A.

The driver device 404 may be coupled to and control the semiconductor dies 402L and 402R using techniques that are well-known in the related arts, which are omitted in the interest of brevity. The semiconductor dies 402L and 402R operate together to provide the functions of the semiconductor die 102 of FIG. 1. Respective aspect ratios of the semiconductor dies 402L and 402R are selected to provide enhanced thermal performance compared to the semiconductor die 102: because operating temperatures in a tub (such as the tub 102A or the tub 402A) increase with increasing distance from the edge of the die, splitting the semiconductor die 102 into two semiconductor dies 402L and 402R and configuring each of the two semiconductor dies to be substantially longer than they are wide will operate to produce lower peak temperatures in the semiconductor dies 402L and 402R than would occur in the semiconductor die 102 under the same operating conditions.

Furthermore, splitting the semiconductor die 102 into two semiconductor dies 402L and 402R and disposing them on either side of the driver device 404 may operate to reduce the lengths of the interconnects between the driver device 404 and the semiconductor dies 402L and 402R, improving the electrical characteristics of those interconnects.

Finally, disposing the two semiconductor dies 402L and 402R created by splitting the semiconductor die 102 at spaced apart locations on the substrate 406 may further improve the thermal characteristics of the electronic module 400 by spreading out the thermal load on the substrate 406.

FIG. 5 is a plan view of an electronic module 500 according to another embodiment.

The electronic module 500 includes a driver device 504, a plurality of left semiconductor dies 502L, and a plurality of right semiconductor dies 502R, all disposed on a substrate 506. Each of the semiconductor dies 502L and 502R includes a single tub 502A disposed with an inactive region 502N that may have a substantially larger area than the corresponding single tub 502A.

The driver device 504 may be coupled to and control the semiconductor dies 502L and 502R using techniques that are well-known in the related arts, which are omitted in the interest of brevity.

The semiconductor dies 502L and 502R operate together to provide the functions of the semiconductor die 102 of FIG. 1. The number of and respective dimensions of the semiconductor dies 502L and 502R are selected to provide enhanced thermal performance compared to the semiconductor die 102: because operating temperatures in a tub (such as the tub 102A or the tub 502A) increase with increasing distance from the edge of the die, splitting the semiconductor die 102 into substantially smaller semiconductor dies 502L and 502R will operate to produce lower peak temperatures in the semiconductor dies 502L and 502R than would occur in the semiconductor die 102 under the same operating conditions.

Furthermore, splitting the semiconductor die 102 into smaller semiconductor dies 502L and 502R and disposing the smaller semiconductor dies 502L and 502R spaced apart from each other (and, in some embodiments, on either sides of the driver device 504) on the substrate 506 may further improve the thermal characteristics of the electronic module 500 by spreading out the thermal load on the substrate 506.

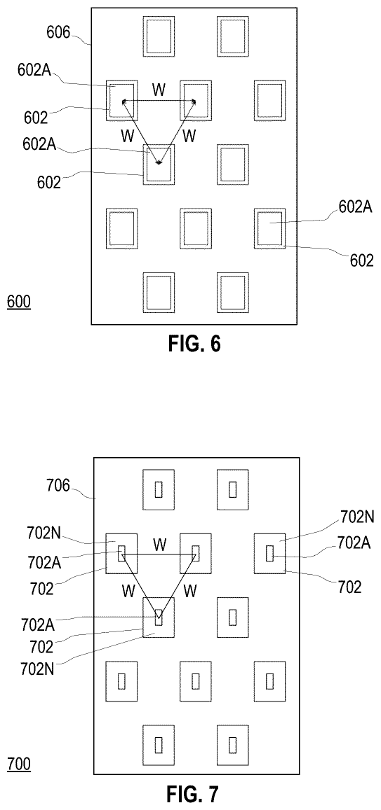

FIG. 6 is a plan view of an electronic module 600 according to another embodiment. The electronic module 600 comprises a plurality of semiconductor dies 602 disposed on substrate 606. Each of the semiconductor dies 602 includes a tub 602A that occupies a substantial majority of the area of that semiconductor die 602. As in the previous embodiments, the semiconductor dies 602 are controlled by one or more driver devices (not shown) to together perform the functions of the semiconductor die 102 of FIG. 1.

The semiconductor dies 602 are disposed in a hexagonal pattern such that a center-to-center distance W between adjacent semiconductor dies 602 are equal. This provides strong thermal decoupling between the semiconductor dies 602 and reduces the area of the substrate 606 needed to safely dissipate (that is, without any of the junction temperatures exceeding a safe limit) the power losses in the electronic module 600.

The embodiment shown in FIG. 6 may be combined with the embodiment shown in FIG. 3, above, by disposing the plurality of left semiconductor dies 302L according to the embodiment of FIG. 6, disposing the plurality of right semiconductor dies 302R according to the embodiment of FIG. 6, or both.

FIG. 7 is a plan view of an electronic module 700 according to another embodiment. The electronic module 700 comprises a plurality of semiconductor dies 702 disposed on substrate 706. The electronic module 700 differs from the electronic module 600 of FIG. 6 in that each of the semiconductor dies 702 includes a tub 702A disposed within an inactive area 702N, and the inactive area 702N occupies a substantial majority of the area of that semiconductor die 702. As in the previous embodiments, the semiconductor dies 702 are controlled by one or more driver devices (not shown) to together perform the functions of the semiconductor die 102 of FIG. 1.

The semiconductor dies 702 are disposed in a hexagonal pattern such that a center-to-center distance W between the respective tubs of adjacent semiconductor dies 702 are equal. This provides strong thermal decoupling between the semiconductor dies 702 and reduces the area of the substrate 706 needed to safely dissipate the power losses in the electronic module 700.

The embodiment shown in FIG. 7 may be combined with the embodiment shown in FIG. 5, above, by disposing the plurality of left semiconductor dies 502L according to the embodiment of FIG. 7, disposing the plurality of right semiconductor dies 702R according to the embodiment of FIG. 7, or both.

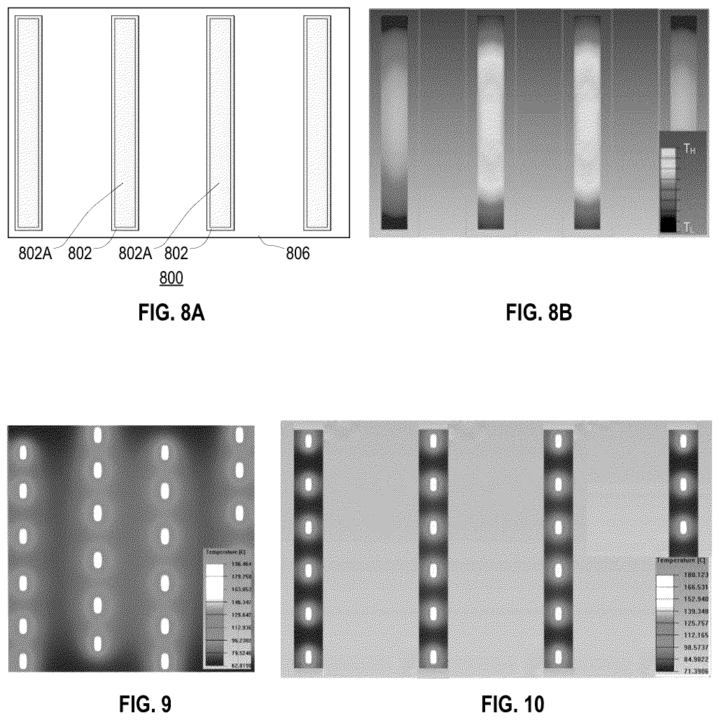

FIG. 8A is a plan view of an electronic module 800 according to another embodiment. The electronic module 800 comprises a plurality of semiconductor dies 802 disposed on substrate 806. Each of the semiconductor dies 802 includes a tub 802A that occupies a substantial majority of the area of that semiconductor die 802. Each of the semiconductor dies 802 has been configured with a high aspect ratio (ratio of length to width). As in the previous embodiments, the semiconductor dies 802 are controlled by one or more driver devices (not shown) to together perform the functions of the semiconductor die 102 of FIG. 1.

The semiconductor dies 802 are disposed in parallel and spaced apart in the direction of their widths. In an embodiment, a center-to-center distance between adjacent semiconductor dies 802 may be equal. This provides strong thermal decoupling between the semiconductor dies 802 and reduces the area of the substrate 806 needed to safely dissipate the power losses in the electronic module 800.

The embodiment shown in FIG. 8A may be combined with the embodiment shown in FIG. 2, above, by replacing the left semiconductor dies 202L with a first plurality of semiconductor dies 802 disposed according to the embodiment of FIG. 8, replacing the right semiconductor dies 202R with a second plurality of semiconductor dies 802 disposed according to the embodiment of FIG. 8, or both.

Furthermore, a plurality of semiconductor dies each similar to the semiconductor dies 402L or 402R of FIG. 4, above, may be disposed according to the embodiment shown in FIG. 8A, and accordingly the embodiment shown in FIG. 8A may be combined with the embodiment shown in FIG. 4 by replacing the left semiconductor dies 402L with a first plurality of semiconductor dies of the same design disposed according to the embodiment of FIG. 8A, replacing the right semiconductor dies 202R with a second plurality of semiconductor dies of the same design disposed according to the embodiment of FIG. 8A, or both.

FIG. 8B is a thermal analysis of the electronic module of FIG. 8A according to an embodiment. The thermal analysis of FIG. 8B may be compared to the thermal analysis of FIG. 1B to illustrate the advantages of the invention.

In FIG. 1B, the temperatures are from an analysis of a 6.75 mm×6.85 mm semiconductor die according to the related arts disposed on a substrate and dissipating 375 watts under predetermined operating conditions. In FIG. 8B the temperatures are from an analysis of four 0.84 mm×6.85 mm semiconductor dies disposed on a substrate according to the embodiment of FIG. 8A and together dissipating 375 watts under the same predetermined operating conditions.

In the analysis for the electronic module of the related arts, a maximum junction temperature was 105.4° C. In the analysis for the device according to the embodiment of FIG. 8A, a maximum junction temperature was 103.4° C.

Thus, the embodiment of FIG. 8A dissipates the same power as the device of the related arts with a slightly lower junction temperature, but the four 0.84 mm×6.85 mm semiconductor dies of the embodiment of FIG. 8A use, in total, approximately half as much semiconductor area as the semiconductor die of the related arts analyzed in FIG. 1B.

FIG. 9 is a thermal analysis of an electronic module of the related arts including a single semiconductor die having a plurality of tubs disposed in columns, with adjacent columns being vertically offset from each other. The semiconductor die is 6.75 mm×6.85 mm and, in the analysis, dissipates 375 watts under predetermined operating conditions.

FIG. 10 is a thermal analysis of an electronic module according to an embodiment, and specifically an electronic module comprising a plurality of semiconductor dies similar to the semiconductor dies 402L and 402R of FIG. 4 disposed on a substrate in accordance with the embodiment of FIG. 8A. Each of the semiconductor die is 0.84 mm×6.85 mm, and in the analysis the plurality of semiconductor dies together dissipate 375 watts under the predetermined operating conditions.

In the analysis, the device of FIG. 9 of the related arts had a maximum junction temperature was 196.5° C. In the analysis for the device of FIG. 10 according to the embodiment, a maximum junction temperature was 180.1° C.

Thus, the embodiment analyzed in FIG. 10 dissipates the same power as the device of the related arts analyzed in FIG. 9 with a lower maximum junction temperature, but the four 0.84 mm×6.85 mm semiconductor dies of the embodiment of FIG. 10 use, in total, approximately half as much semiconductor area as the semiconductor die of the related arts analyzed in FIG. 9.

Illustrative embodiments have been provided wherein functions of an electronic module that would be performed in a single die in the related arts are partitioned into a plurality of semiconductor dies that have a high aspect ratio that improves the amount of heat that can be removed from each semiconductor die at a given maximum junction temperature, are disposed on a substrate in a manner that improves the amount of heat that can be removed from each semiconductor die at a given maximum junction temperature, or both.

In the illustrative embodiments, the semiconductor dies are substantially identical to each other; however, embodiments are not limited thereto.

In some embodiments, the semiconductor dies each include only a single tub. In other embodiments, the semiconductor dies each include multiple tubs.

In some embodiments, the semiconductor dies each include a substantial inactive area, and in some such embodiments the tubs occupy less than half of the area of the semiconductor die.

In other embodiments, the tubs occupy substantially more than half of the area of each semiconductor die.

In embodiments, the electronic module includes a driver device that is coupled to and controls the semiconductor dies and that is disposed between two semiconductor dies. In some such embodiments, the driver device is disposed between a first plurality of semiconductor dies and a second plurality of semiconductor dies.

In embodiments, disposing a plurality of semiconductor dies on a substrate in a manner that improves the amount of heat that can be removed from each semiconductor die at a given maximum junction temperature comprises disposing the dies such that center-to-center distances between all adjacent pairs of die are the same. In some such an embodiment, the plurality of semiconductor dies may be arranged in a hexagonal pattern. In other such embodiments, the plurality of semiconductor dies may be arranged in a rectangular-array pattern (including in a one-dimensional rectangular array pattern).

The designs shown in the illustrated embodiments may be combined. For example, a plurality of semiconductor dies having a high length-to-width aspect ratio may be arranged a one-dimensional rectangular array pattern along the axis corresponding to their width.

Aspects of the present disclosure have been described in conjunction with the specific embodiments that are presented as illustrative examples. Numerous alternatives, modifications, and variations to the disclosed embodiments may be made without departing from the scope of the claims set forth below. Embodiments disclosed herein are not intended to be limiting.

What is claimed is:

1. An electronic module comprising:
a substrate; and
a plurality of semiconductor dies disposed on the substrate;
wherein the plurality of semiconductor dies operate together to perform a power device function, and
wherein the plurality of semiconductor dies are shaped, disposed on the substrate, or both to improve a thermal performance of the electronic module.

2. The electronic module of claim 1, further comprising:
a driver device coupled to and configured to control the plurality of semiconductor dies,
wherein the driver device is disposed on the substrate between a first semiconductor die of the plurality of semiconductor dies and a second semiconductor die of the plurality of semiconductor dies.

3. The electronic module of claim 2,
wherein the plurality of semiconductor dies includes a first group comprising two or more of the semiconductor dies and a second group comprising two or more of the semiconductor dies, and
wherein the driver device is disposed on the substrate between the first group and the second group.

4. The electronic module of claim 1, wherein shaping the plurality of semiconductor dies to improve the thermal performance includes configuring a length of a semiconductor die of the plurality of semiconductor dies to be four or more times a width of the semiconductor die.

5. The electronic module of claim 1, wherein shaping the plurality of semiconductor dies to improve the thermal performance includes configuring a length of a semiconductor die of the plurality of semiconductor dies to be eight or more times a width of the semiconductor die.

6. The electronic module of claim 1,
wherein the plurality of semiconductor dies includes at least three semiconductor dies, and
wherein disposing the plurality of semiconductor dies on the substrate to improve the thermal performance includes disposing the semiconductor dies such that center-to-center distances between adjacent semiconductor dies are the same.

7. The electronic module of claim 6, wherein the plurality of dies are disposed in a hexagonal pattern.

8. The electronic module of claim 6, wherein the plurality of semiconductor dies are disposed in a linear or rectangular pattern.

9. The electronic module of claim 1, wherein each semiconductor die of the plurality of semiconductor dies includes only one tub.

10. The electronic module of claim 9, wherein each semiconductor die of the plurality of semiconductor dies includes an inactive region occupying an area greater than the one tub.

11. The electronic module of claim 1, wherein each semiconductor die of the plurality of semiconductor dies includes a plurality of tubs.

12. The electronic module of claim 11, wherein each semiconductor die of the plurality of semiconductor dies includes an inactive region occupying an area greater than the plurality of tubs.

13. The electronic module of claim 1, wherein the semiconductor dies of the plurality of semiconductor dies are identical to each other.

14. The electronic module of claim 1, wherein each semiconductor die of the plurality of semiconductor dies is a silicon carbide power device.

15. The electronic module of claim 1, wherein each semiconductor die of the plurality of semiconductor dies is a gallium nitride power device.

16. The electronic module of claim 1, wherein each semiconductor die of the plurality of semiconductor dies is a vertical device having a source or drain terminal on a surface of the semiconductor die in contact with the substrate.
